(19) United States
(12) Patent Application Publication
(10) Pub. No.: US 2024/0349425 A1
(43) Pub. Date: Oct. 17, 2024

(54) ELECTRICALLY CONDUCTIVE FILM AND METHOD FOR MANUFACTURING SAME, AND DISPLAY DEVICE

(71) Applicant: TDK CORPORATION, Tokyo (JP)

(72) Inventors: Yoshihisa TAMAGAWA, Tokyo (JP); Hiroshi SHINGAI, Tokyo (JP); Daisuke SONODA, Tokyo (JP); Keisuke NISHIOKA, Tokyo (JP); Ken NODA, Tokyo (JP)

(73) Assignee: TDK CORPORATION, Tokyo (JP)

(21) Appl. No.: 18/683,879

(22) PCT Filed: Aug. 17, 2022
(86) PCT No.: PCT/JP2022/031079

§ 371 Date: Feb. 15, 2024

(30) Foreign Application Priority Data
Aug. 17, 2021 (JP) 2021-132679

(51) Int. Cl. H05K 1/09; G02F 1/1345; H05K 3/10

(52) U.S. Cl. CPC H05K 1/095; H05K 3/107; G02F 1/1345; H05K 2201/10136; H05K 2203/10

(57) ABSTRACT

An electrically conductive film including a film-like base material, and a resin layer and an electrically conductive part provided on a main surface of the base material is disclosed. The resin layer has a pattern including a linear trench. The electrically conductive part has a portion provided in the linear trench. The resin layer has raised portions formed along the trench on both sides of the linear trench and raised in the thickness direction of the resin layer.

### TECHNICAL FIELD

The present disclosure relates to an electrically conductive film, a method for manufacturing the same, and a display device.

### BACKGROUND ART

In a display device such as a liquid crystal display device, an electrically conductive member having a conductor portion formed of a thin metal wire and having a pattern including an opening may be used (e.g., Patent Document 1).

### CITATION LIST

### Patent Literature

Patent Literature 1: WO 2019/093049 A

### SUMMARY OF INVENTION

### Technical Problem

The present disclosure relates to a novel electrically conductive film that can be used for a display device or the like.

### Solution to Problem

The present disclosure includes at least the following aspects.

[1] electrically conductive film including a film-like base material, and a resin layer and an electrically conductive part provided on one or both main surfaces of the base material; wherein
the resin layer has a pattern including a linear trench,
the electrically conductive part has a portion provided in the linear trench, and
the resin layer has raised portions formed along the trench on both sides of the linear trench, the raised portions raised in a thickness direction of the resin layer.

[2] The electrically conductive film described in [1], wherein
a main surface of the resin layer positioned on a side opposite to the base material includes a parallel surface parallel to the main surface of the base material, and
a height of the raised portions with respect to the parallel surface is greater than or equal to 0.17 μm.

[3] The electrically conductive film described in [1] or [2], wherein
a height of the electrically conductive part from the base material is smaller than a height of the raised portions from the base material.

[4] The electrically conductive film described in any one of [1] to [3], wherein
the pattern includes a plurality of the linear trenches intersecting each other.

[5] The electrically conductive film described in [4], wherein
the pattern is a mesh-like pattern.

[6] The electrically conductive film described in [4] or [5],
wherein a height of the raised portions from the base material in the vicinity of an intersecting part where the two linear trenches intersect is larger than a height of the raised portions from the base material at a position away from the intersecting part.

[7] A display device including the electrically conductive film described in any one of [1] to [6].

[8] A method for manufacturing an electrically conductive film including:
pushing a mold having a linear protrusion into a resin layer provided on one or both main surface sides of a film-like base material, and then pulling out the mold from the resin layer to form a pattern including a linear trench in the resin layer; and
forming an electrically conductive part including a portion provided in the linear trench; wherein
the mold is pushed into the resin layer such that the resin layer forms raised portions raised in a thickness direction of the resin layer along the trench on both sides of the linear trench.

[9] The method described in [8], wherein
a main surface positioned on a side opposite to the base material of the resin layer having the pattern includes a parallel surface parallel to the main surface of the base material, and
a height of the raised portions with respect to the parallel surface is greater than or equal to 0.17 μm.

[10] The method described in [8] or [9], wherein
a height of the electrically conductive part from the base material is less than a height of the raised portions from the base material.

[11] The method described in any one of [8] to [10], wherein
the pattern includes a plurality of the linear trenches intersecting each other.

[12] The method described in [11], wherein
the pattern is a mesh-like pattern.

[13] The method described in or [12], wherein
a height of the raised portions from the base material in the vicinity of an intersecting part where the two linear trenches intersect is larger than a height of the raised portions from the base material at a position away from the intersecting part.

[14] The method described in any one of [8] to [13], wherein
the resin layer before the mold is pushed in contains a photocurable resin composition, and
the resin layer is cured by irradiating the resin layer with ultraviolet rays in a state where the mold is pushed into the resin layer.

[15] The method described in any one of [8] to [14], wherein
the electrically conductive part is formed by a plating method.

[16] An electrically conductive film manufactured by the method

described in any one of [8] to [15].

### Advantageous Effects of Invention

An electrically conductive film according to one aspect of the present disclosure can constitute a wiring having good conductivity.

### BRIEF DESCRIPTION OF DRAWINGS

FIG. 1 is a plan view illustrating an example of an electrically conductive film.

FIG. 2 is a cross-sectional view taken along line II-II in FIG. 1.

FIG. 3 is an enlarged plan view illustrating an example of an intersecting part of trenches.

FIG. 4 is an enlarged cross-sectional view taken along line IV-IV in FIG. 3.

FIG. 5 is a cross-sectional view illustrating another example of the electrically conductive film.

FIG. 6 is an enlarged cross-sectional view illustrating another example of the electrically conductive film.

FIG. 7 is a cross-sectional view illustrating an example of a display device including an electrically conductive film.

### DESCRIPTION OF EMBODIMENTS

The present invention is not limited to the following examples.

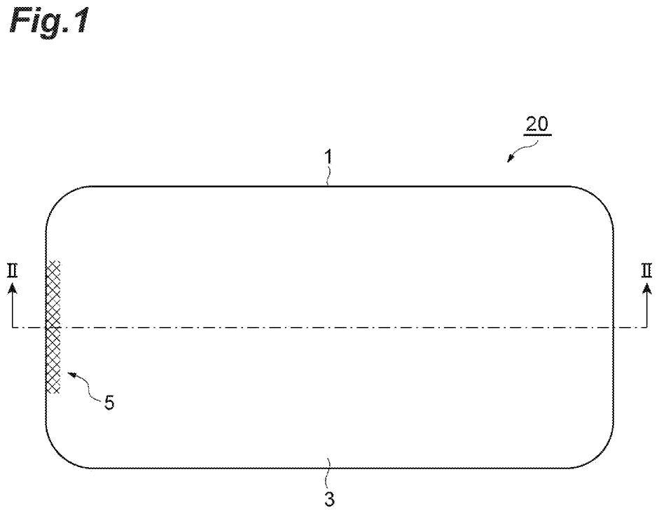

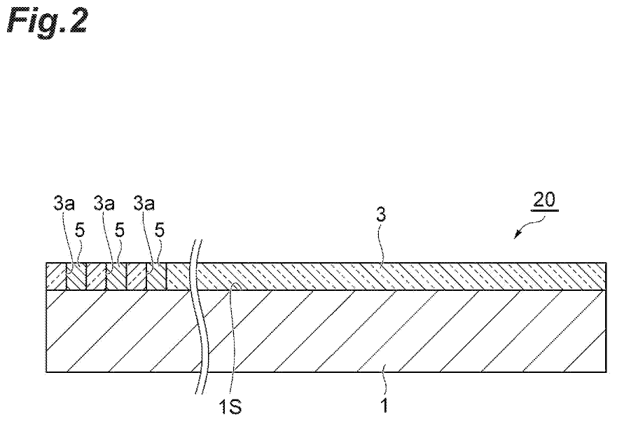

FIG. 1 is a plan view illustrating an example of an electrically conductive film. FIG. 2 is a cross-sectional view taken along line II-II in FIG. 1. An electrically conductive film 20 shown in FIGS. 1 and 2 mainly includes a film-like base material 1, and a resin layer 3 and an electrically conductive part 5 provided on one main surface 1S side of the base material 1. The resin layer 3 has a pattern including a plurality of linear trenches 3a. The electrically conductive part 5 has a portion (linear portion) provided in the linear trench 3a. In the examples of FIGS. 1 and 2, a mesh-like pattern is formed by intersecting a plurality of linear trenches 3a extending along each of the two directions. The electrically conductive part 5 in the trench 3a also forms a mesh-like pattern. The electrically conductive part 5 having the mesh-like pattern can function well as, for example, a radiating element of an antenna. The trench 3a and the electrically conductive part 5 are provided over a partial region of the main surface 1S of the base material 1. A resin layer and an electrically conductive part may be further provided on a main surface of the base material 1 positioned on a side opposite to the main surface 1S.

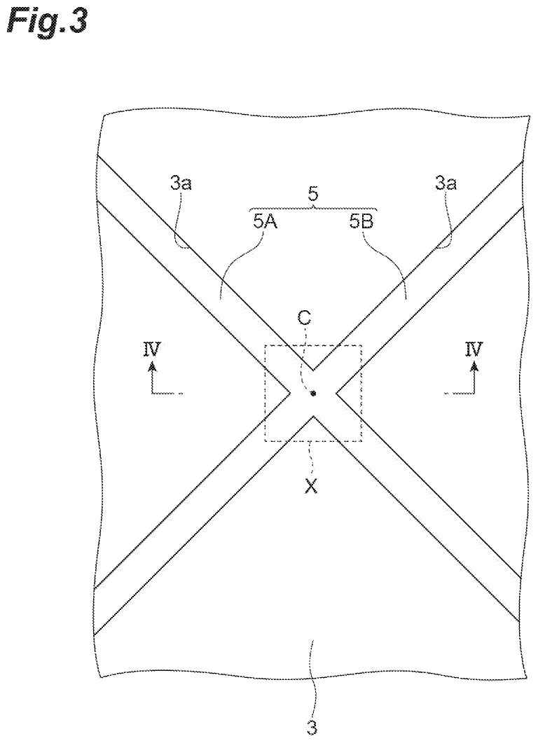

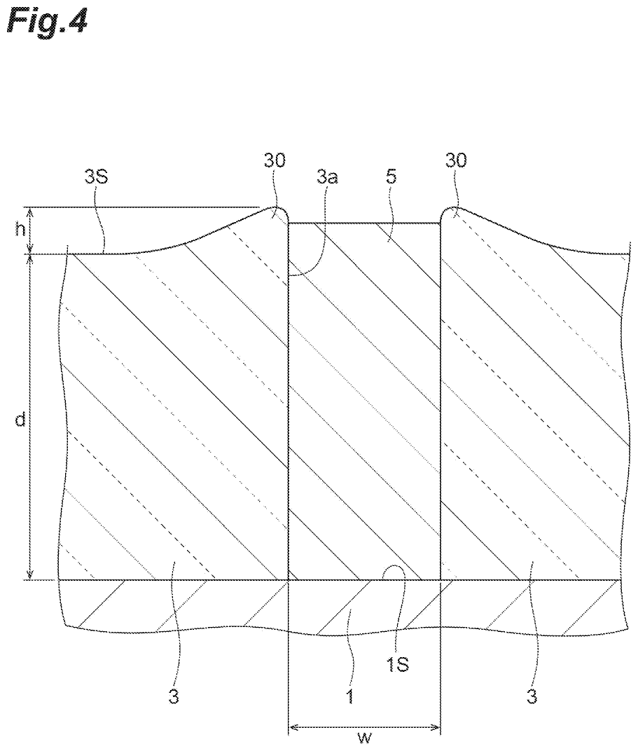

FIG. 3 is an enlarged plan view of the vicinity of an intersecting part X where two linear trenches 3a and two linear portions 5A and 5B of the electrically conductive part 5 intersect each other. FIG. 4 is an enlarged cross-sectional view taken along line IV-IV in FIG. 3. At the intersecting part X illustrated in FIGS. 3 and 4, the two linear trenches 3a intersect each other at a right angle. The angle between the two linear trenches 3a intersecting each other does not need to be 90 degrees, and can be, for example, in a range of greater than or equal to 40 degrees and smaller than or equal to 140 degrees.

As illustrated in FIG. 4, the resin layer 3 has raised portions 30 formed on both sides of the linear trench 3a and raised in the thickness direction of the resin layer 3. The raised portions 30 extends along the trench 3a. The main surface of the resin layer 3, which is positioned on a side opposite to the base material 1, includes a parallel surface 3S parallel to the main surface 1S of the base material 1 on the inner side of the raised portions 30 (side away from the trench 3a). The raised portions 30 include a portion where the thickness of the resin layer 3 increases toward the trench 3a. The vertex of the raised portions 30, that is, the point at which the height h of the raised portions with respect to the parallel surface 3S is the maximum is located near both sides of the trench 3a. When viewed from a direction perpendicular to the main surface 1S of the base material 1, the distance between the end face of the resin layer 3 (the wall surface of the trench 3a) at a position where the trench 3a exhibits the minimum width and the vertex of the raised portions 30 may be greater than or equal to 0.0 μm and less than or equal to 5.0 μm, or greater than or equal to 0.0 μm and less than or equal to 4.0 μm. If the resin layer 3 has the raised portions 30, adhesiveness of the electrically conductive film to other members provided on the resin layer 3 side can be improved. In addition, the electrically conductive part 5 having stable and satisfactory conductivity is easily formed.

When the height h of the raised portions with respect to the parallel surface 3S is greater than or equal to 0.17 μm, satisfactory conductivity is particularly easily maintained even when the width of the electrically conductive part 5 is small. From the same point of view, the height h of the raised portions 30 with respect to the parallel surface 3S may be greater than or equal to 0.18 μm. The height h of the raised portions may be less than or equal to 0.30 μm or less than or equal to 0.25 μm.

The height h of the raised portions can be measured in the vicinity of an arbitrary position of the trench 3a, and can be, for example, a value obtained by continuously measuring the height of the resin layer 3 along a straight line passing through the center C of the intersecting part X of the two linear trenches 3a and equally dividing the corner between the two linear trenches 3a. The center C of the intersecting part X is an intersection of center lines equally dividing each of the two linear trenches 3a. The height of the resin layer 3 is continuously measured by, for example, a scanning white interference microscope. The height of the raised portions 30 with respect to the main surface 1S (or the parallel surface 3S) of the base material 1 in the vicinity of the intersecting part X, which is obtained by the above method, may be larger than the height of the raised portions 30 with respect to the main surface 1S (or the parallel surface 3S) of the base material 1 at a position away from the intersecting part X.

The depth d of the trench 3a with respect to the parallel surface 3S may be larger than or equal to 1.0 μm, and may be less than or equal to 5.0 μm, less than or equal to 4.0 μm, or less than or equal to 3.0 μm. The minimum width w of the trench 3a may be larger than or equal to 0.5 μm or larger than or equal to 1.0 μm, and may be less than or equal to 3.0 μm, less than or equal to 2.5 μm, or less than or equal to 2.0 μm. The depth d of the trench 3a usually coincides with the thickness of the resin layer 3 at the portion forming the parallel surface 3S. The height of the electrically conductive part 5 with respect to the main surface 1S of the base material 1 can be in a similar range as the depth d of the trench 3a. The minimum width of the electrically conductive part 5 can be in a similar range as the minimum width w of the trench 3a. In the electrically conductive film according to the present disclosure, even an electrically conductive part having such a fine size can stably have good conductivity.

The height (maximum height) of the electrically conductive part 5 with respect to the main surface 1S of the base material 1 may be smaller than the height (d+h) of the raised portions 30 with respect to the main surface 1S of the base material 1. As a result, it is possible to suppress diffusion of the electrically conductive material constituting the electrically conductive part 5 into the region other than the trench 3a.

The ratio (=h/(d+h)×100) of the height with respect to the parallel surface 3S of the raised portions 30 to the height of the raised portions 30 with respect to the main surface 1S of the base material 1 may be greater than or equal to 8.0% or greater than or equal to 9.0%, and may be less than or equal to 20% or less than or equal to 15%. In this case as well, even when the width of the electrically conductive part 5 is small, good conductivity is particularly easily maintained.

The base material 1 may be a light transmissive base material. The light transmissive base material has, for example, light transmissivity to an extent required when the electrically conductive film 20 is incorporated in a display device. Specifically, the total light transmittance of the light transmissive base material may be 90 to 100%. The light transmissive base material may have a haze of 0 to 5%.

The light transmissive base material used as the base material 1 may be, for example, a transparent resin film, and examples thereof include a film of polyethylene terephthalate (PET), polycarbonate (PC), polyethylene naphthalate (PEN), cycloolefin polymer (COP), or polyimide (PI). Alternatively, the light transmissive base material may be a glass substrate.

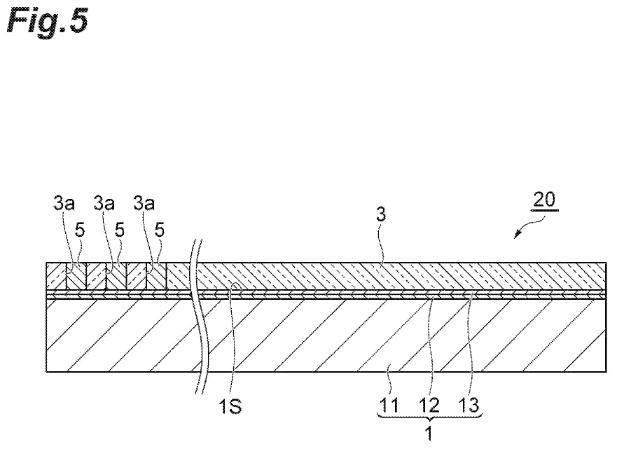

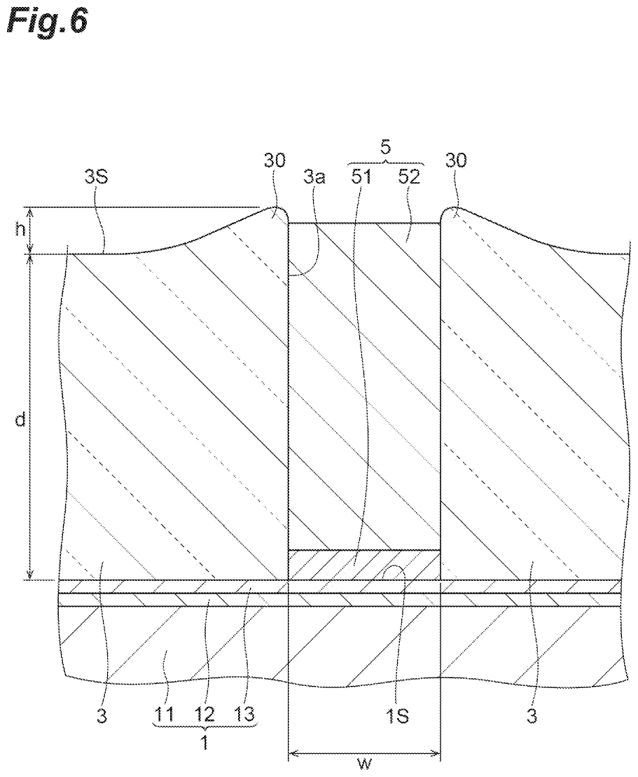

FIG. 5 is a cross-sectional view showing another example of the electrically conductive film, and FIG. 6 is an enlarged cross-sectional view of the electrically conductive film of FIG. 5. As in the examples of FIGS. 5 and 6, the base material 1 may be a laminate including a support film 11, and an intermediate resin layer 12 and an underlying layer 13 sequentially provided on the support film 11. The support film 11 can be, for example, the light transmissive base material. The underlying layer 13 is a layer provided in order to form the electrically conductive part 5 by electroless plating or the like. In a case where the electrically conductive part 5 is formed by another method, the underlying layer 13 may not be necessarily provided. It is not essential that the intermediate resin layer 12 is provided between the support film 11 and the underlying layer 13.

The thickness of the base material 1 or the support film 11 constituting the same may be greater than or equal to 10 μm, greater than or equal to 20 μm, or greater than or equal to 35 μm, and may be less than or equal to 500 μm, less than or equal to 200 μm, or less than or equal to 100 μm.

Adhesion between the support film 11 and the underlying layer 13 can be improved by providing the intermediate resin layer 12. In a case where the underlying layer 13 is not provided, the intermediate resin layer 12 is provided between the support film 11 and the resin layer 3, so that adhesion between the support film 11 and the resin layer 3 can be improved.

The intermediate resin layer 12 may be a layer containing a resin and an inorganic filler. Examples of the resin constituting the intermediate resin layer 12 include an acrylic resin. Examples of the inorganic filler include silica.

The thickness of the intermediate resin layer 12 may be, for example, greater than or equal to 5 nm, greater than or equal to 100 nm, or greater than or equal to 200 nm, and may be less than or equal to 10 μm, less than or equal to 5 μm, or less than or equal to 2 μm.

The underlying layer 13 may be a layer containing a catalyst and a resin. The resin may be a cured product of a curable resin composition. Examples of the curable resin contained in the curable resin composition include an amino resin, a cyanate resin, an isocyanate resin, a polyimide resin, an epoxy resin, an oxetane resin, a polyester, an allyl resin, a phenol resin, a benzoxazine resin, a xylene resin, a ketone resin, a furan resin, a COPNA resin, a silicon resin, a diclopentadiene resin, a benzocyclobutene resin, an episulfide resin, an ene-thiol resin, a polyazomethine resin, a polyvinyl benzyl ether compound, acenaphthylene, and an ultraviolet curable resin. The ultraviolet curable resin contains a functional group that causes a polymerization reaction by ultraviolet rays such as an unsaturated double bond, a cyclic ether, and a vinyl ether.

The catalyst contained in the underlying layer 13 may be an electroless plating catalyst. The electroless plating catalyst may be a metal selected from Pd, Cu, Ni, Co, Au, Ag, Pd, Rh, Pt, In, and Sn, or may be Pd. The catalyst may be one kind alone or a combination of two or more kinds. Usually, the catalyst is dispersed in the resin as catalyst particles.

The content of the catalyst in the underlying layer 13 may be greater than or equal to 3 mass %, greater than or equal to 4 mass %, or greater than or equal to 5 mass %, and may be less than or equal to 50 mass %, less than or equal to 40 mass %, or less than or equal to 25 mass % with respect to the total amount of the underlying layer 13.

The thickness of the underlying layer 13 may be, for example, greater than or equal to 10 nm, greater than or equal to 20 nm, or greater than or equal to 30 nm, and may be less than or equal to 500 nm, less than or equal to 300 nm, or less than or equal to 150 nm.

The base material 1 may further include a protective layer provided on a main surface of the support film 11 on a side opposite to the resin layer 3 and the electrically conductive part 5. Providing the protective layer prevents the support film 11 from being scratched. The protective layer can be a layer similar to the intermediate resin layer 12. The thickness of the protective layer may be, for example, greater than or equal to 5 nm, greater than or equal to 50 nm, or greater than or equal to 500 nm, and may be less than or equal to 10 μm, less than or equal to 5 μm, or less than or equal to 2 μm.

The electrically conductive part 5 may contain metal as an electrically conductive material. The electrically conductive part 5 may contain at least one type of metal selected from copper, nickel, cobalt, palladium, silver, gold, platinum, and tin, or may contain copper. The electrically conductive part 5 may be metal plating formed by a plating method. The electrically conductive part 5 may further contain a nonmetallic element such as phosphorus as long as appropriate conductivity is maintained.

The electrically conductive part 5 may be a laminate including a plurality of layers. For example, as illustrated in FIG. 6, the electrically conductive part 5 may include a first metal layer 51 and a second metal layer 52 sequentially formed from the main surface 1S side of the base material 1. The first metal layer 51 may contain nickel. The second metal layer 52 may contain copper. The thickness of the first metal layer 51 may be, for example, greater than or equal to 5 nm, greater than or equal to 10 nm, or greater than or equal to 50 nm, and may be less than or equal to 500 nm, less than or equal to 200 nm, or less than or equal to 100 nm. When the underlying layer 13 is not provided, the first metal layer 51 (or the electrically conductive part 5) can be formed on the intermediate resin layer 12. When the intermediate resin layer 12 and the underlying layer 13 are not provided, the first metal layer 51 (or the electrically conductive part 5) can be formed on the support film 11.

The electrically conductive part 5 may have a blackened layer as a surface layer portion on a side opposite to the base material 1. The blackened layer can contribute to improvement in visibility of a display device in which the electrically conductive film is incorporated. The blackened layer may be a layer similar to the first metal layer 51, and may be, for example, a layer containing copper and nickel. In this case, the content of nickel in the blackened layer may be greater than or equal to 15 mass % and less than or equal to 60 mass % with respect to the total amount of copper and nickel. The thickness of the blackened layer may be, for example, greater than or equal to 300 nm and less than or equal to 400 nm. The blackened layer may be a layer formed by treating the electrically conductive part 5 with a treatment liquid containing Pd.

The resin layer 3 may be a layer formed of resin having light transmissivity. The total light transmittance of the resin layer 3 may be 90 to 100%. The resin layer 3 may have a haze of 0 to 5%.

The resin that forms the resin layer 3 may be a cured product of a curable resin composition (photocurable resin composition or thermosetting resin composition). The curable resin composition that forms the resin layer 3 contains a curable resin. Examples of the curable resin include an acrylic resin, an amino resin, a cyanate resin, an isocyanate resin, a polyimide resin, an epoxy resin, an oxetane resin, a polyester, an allyl resin, a phenol resin, a benzoxazine resin, a xylene resin, a ketone resin, a furan resin, a COPNA resin, a silicon resin, a diclopentadiene resin, a benzocyclobutene resin, an episulfide resin, an ene-thiol resin, a polyazomethine resin, a polyvinyl benzyl ether compound, acenaphthylene, and an ultraviolet curable resin. The ultraviolet curable resin contains a functional group that causes a polymerization reaction by ultraviolet rays such as an unsaturated double bond, a cyclic ether, and a vinyl ether.

The electrically conductive film 20 can be manufactured, for example, by a method including pattern formation by the imprinting method. An example of a method for manufacturing the electrically conductive film 20 includes preparing a film-like base material 1 including a support film and an underlying layer that is provided on one main surface of the support film and contains a catalyst; providing a resin layer 3 on a main surface 1S of the base material 1; forming a pattern including a linear trench 3a in the resin layer 3 by pushing a mold having a linear protrusion into the resin layer 3 and then subsequently pulling out the mold from the resin layer 3; and forming an electrically conductive part 5 including a linear portion provided in the linear trench 3a by a plating method including growing a metal plating from the underlying layer exposed in the trench 5a. When the resin layer 3 is a layer containing a curable resin composition, the resin layer 3 may be cured in a state where a mold is pushed into the resin layer 3. When the resin layer 3 contains a photocurable resin composition, the resin layer 3 may be irradiated with ultraviolet rays in a state where the mold is pushed into the resin layer 3, thereby curing the resin layer 3.

The mold used in the imprinting method is pushed into the resin layer 3 so that the resin layer 3 forms the raised portions 30. For example, the raised portions 30 can be formed on the resin layer 3 by controlling the magnitude of the pressure applied to the resin layer 3 by the mold. When the pressure applied to the resin layer by the protrusion of the mold is large, the height h of the raised portions tends to increase. For example, the resin layer 3 having the raised portion 30 can be easily formed by adjusting the pressure applied to the resin layer by the protrusion of the mold in the range of greater than or equal to 0.20 MPa or greater than or equal to 0.25 MPa. The pressure applied to the resin layer by the protrusion of the mold may be less than or equal to 2.0 MPa or less than or equal to 1.5 MPa.

When a part of the resin layer remains at the bottom of the trench 3a after the formation of the trench 3a by the imprinting method, this may be removed before the formation of the electrically conductive part 5. However, when the trench 3a is formed by the imprinting method under the condition that the raised portions 30 are sufficiently formed, the electrically conductive part 5 having good conductivity can be efficiently formed by the plating method without requiring removal of the remaining resin layer.

The formation of the electrically conductive part 5 by the plating method may include, for example, forming a seed layer on the underlying layer by an electroless plating method, and forming Cu plating on the seed layer by an electroless plating method. In this case, the seed layer may be the first metal layer 51, and the Cu plating may be the second metal layer 52.

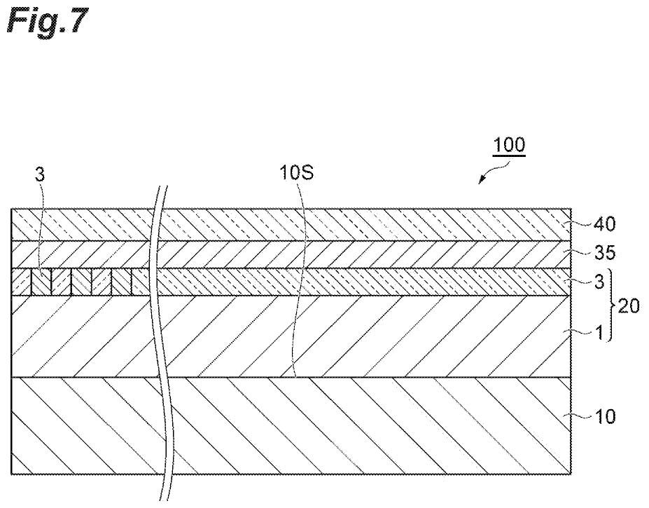

The electrically conductive film exemplarily described above can be incorporated in a display device as, for example, a planar transparent antenna. The display device may be, for example, a liquid crystal display device or an organic EL display device. FIG. 7 is a cross-sectional view illustrating an example of a display device in which an electrically conductive film is incorporated. A display device 100 illustrated in FIG. 7 includes an image display unit 10 having an image display region 10S, an electrically conductive film 20, a polarizing plate 35, and a cover glass 40. The electrically conductive film 20, the polarizing plate 35, and the cover glass 40 are laminated, in this order from the image display unit 10 side, on the image display region 10S side of the image display unit 10. The configuration of the display device is not limited to the form of FIG. 7, and can be appropriately changed as necessary. For example, the polarizing plate 35 may be provided between the image display unit 10 and the electrically conductive film 20. The image display unit 10 may be, for example, a liquid crystal display unit. As the polarizing plate 35 and the cover glass 40, those commonly used in a display device can be used. The polarizing plate 35 and the cover glass 40 may not be necessarily provided.

### EXAMPLES

The present invention is not limited to the following examples.

### 1. Mold

A mold having a width L of 1 μm or 2 μm and having a plurality of linear protrusions arrayed at a spacing S of 100 μm or 200 μm was prepared. The linear protrusions of the mold intersected each other at a right angle to form a mesh-like pattern.

### 2. Imprint Molding Test

A curable resin for forming an underlying layer containing Pd particles was prepared. This curable resin was coated onto a polyethylene terephthalate (PET) film (thickness: 100 μm), that is a transparent base material, using a bar coater. The coated film was heated to 80° C. and cured to form an underlying layer (thickness: 100 nm). A photocurable resin composition containing an oligomer having an acrylic group was coated onto the underlying layer to form a photocurable resin layer (thickness: 2 μm).

The protrusion of the mold was pushed into the formed resin layer so that the tip thereof reaches the underlying layer, and in this state, the ultraviolet curable resin layer was cured by ultraviolet irradiation. By pulling out the protrusion of the mold from the resin layer, a resin layer having a mesh-like pattern including a plurality of linear trenches intersecting each other was formed. The imprint molding test of Test Examples 1 to 6 shown in Table 1 was conducted under several conditions in which the pressure for pushing the protrusion of the mold was different. The pressure at the protrusion of the mold was measured by a pressure-sensitive paper.

### 3. Observation of Trench Shape

The shape of the trench was observed with a scanning white interference microscope (VS1000, Hitachi, Ltd.). A change in the height of the resin layer forming the trench was measured by scanning the surface of the trench of the portion to which the shape of the portion where the linear protrusions having a width of 1 μm and arrayed at a spacing of 100 μm intersect was transferred along a direction of 45 degrees with respect to the trench. A range of 20 μm or 30 μm including a portion where the surface of the resin layer was horizontal was scanned around the intersecting part of the trenches. Other measurement conditions were as follows.
Camera: manufactured by Sony Corporation, XCL-C30 1/3
Camera speed: 1.0X
Objective lens: 50 XDI
Lens barrel: 1.0X
Zoom lens: 1.0X
Light source: 530 White
Measuring device: piezo
Measurement mode: WaveT
Scan speed: 4 μm/s
Visual field size: 640×480
Number of effective pixels: 50

From the measurement results, the minimum width w of the trench, the depth d of the trench with respect to the parallel surface parallel to the main surface of the base material of the resin layer, and the height h of the raised portions with respect to the parallel surface of the resin layer were obtained. In Test Example 6, the shape of the trench in the vicinity of the intersecting part of the trenches having a width L of 2 μm and a spacing S of 200 μm was also measured.

### 4. Formation of Electrically Conductive Part

A laminate including a PET film, an underlying layer, and a resin layer was immersed in an alkaline degreasing liquid containing a surfactant for 5 minutes. The laminate taken out from the degreasing liquid was washed with pure water. The washed laminate was immersed in an electroless plating solution containing nickel sulfate and sodium hypophosphite for 3 minutes to grow metal plating serving as a seed layer (thickness: 100 nm) consisting of Ni and P from the underlying layer exposed on the bottom surface of the trench. The laminate taken out from the electroless plating solution was washed with pure water. Subsequently, the laminate on which the seed layer was formed was immersed in an aqueous solution containing Pd for 5 minutes and then washed with pure water to adsorb Pd particles serving as a catalyst to the seed layer. Subsequently, the laminate was immersed in an electroless plating solution containing copper sulfate and formalin for 15 minutes to grow Cu plating (upper metal plating layer) filling the trench on the seed layer. The laminate taken out from the electroless plating solution was washed with pure water and dried at 80° C. for 3 minutes to obtain an electrically conductive film having a mesh-like pattern and having an electrically conductive part including the seed layer and the Cu plating.

### 5. Evaluation

In the case of Test Examples 1 to 3, plating was not deposited from the underlying layer, and no electrically conductive part was formed. This is considered to be because the resin layer remained at the bottom of the trench.

Regarding Test Example 4 to 6 in which the electrically conductive part was formed, the number of portions in which flaws such as defects were recognized in the electrically conductive part was confirmed by microscopic observation. As the observed electrically conductive parts, in a portion where the spacing S between the trenches was 100 μm and the width L of the trench was 1 μm or 2 μm, 6 electrically conductive parts having a length of 200 μm constituting a rectangular portion including four meshes were selected, and in a portion where the spacing S between the trenches was 200 μm and the width L of the trench was 1 μm or 2 μm, 4 electrically conductive parts having a length of 200 μm surrounding one mesh were selected. The number of electrically conductive parts in which flaws were recognized was recorded among 60 electrically conductive parts constituting a total of 40 locations selected by 10 locations from a portion where the spacing S of the trenches was 100 μm and the trench width L was 1 μm or 2 μm, and by 10 locations from a portion where the spacing S of the trenches was 200 μm and the trench width L was 1 μm or 2 μm. Among the 60 electrically conductive parts, the proportion of the electrically conductive part in which no flaw was recognized was obtained as a precision ratio.

In Test Examples 4 to 6, the surface resistance value of the formed electrically conductive part was measured.

TABLE 1

| Test Example | 1 | 2 | 3 | 4 | 5 | 6 | |
|---|---|---|---|---|---|---|---|
| Trench Shape | 1/100 | 1/100 | 1/100 | 1/100 | 1/100 | 1/100 | 2/200 |
| Measurement Position | | | | | | | |
| (L/S) | | | | | | | |
| Width W [μm] | 1.257 | 1.258 | 1.572 | 1.574 | 1.258 | 1.572 | 2.830 |
| Trench Depth D [μm] | 1.926 | 1.926 | 1.852 | 1.787 | 1.813 | 1.802 | 1.873 |
| Raised Portion Height H | 0.102 | 0.104 | 0.153 | 10.171 | 0.180 | 0.212 | 0.232 |
| [μm] | | | | | | | |
| d + h | 2.028 | 2.030 | 2.005 | 1.959 | 1.993 | 2.014 | 2.106 |
| h/(d + h) | 5.0% | 5.1% | 7.6% | 8.7% | 9.0% | 10.5% | 11.0% |

| Pressure [MPa] | | — | — | 0.10 | 0.25 | 0.80 | 1.00 |
|---|---|---|---|---|---|---|---|
| Plating Deposition | | — | — | — | 18% | 76% | 88% |
| Property | | | | | | | |
| (Precision Ratio) | | | | | | | |
| Surface | L/S = 1/100 | — | | — | ∞ | 5.8 | 2.4 |
| Resistance | L/S = 1/200 | — | | — | ∞ | 59.6 | 5.7 |
| Value | L/S = 2/100 | — | | — | ∞ | 1.1 | 0.8 |
| [Ω/Sq.] | L/S = 2/200 | — | | — | 9.3 | 5.5 | 2.4 |

The evaluation results are shown in Table 1. When the width L of the trench was 2 μm and the spacing between the trenches was 200 μm, an electrically conductive part having good conductivity was stably formed without requiring a step of removing the remaining resin layer after the imprint molding under the condition of forming the raised portions as in Test Examples 4 to 6. When forming another finer electrically conductive 10 part, an electrically conductive part having good conductivity was stably formed without removing the remaining resin layer after the imprint molding under the conditions of Test Examples 5 and 6.

### REFERENCE SIGNS LIST

1 base material
1S main surface
3 resin layer
5 electrically conductive part
51 first metal layer
52 second metal layer
3a trench
3S parallel surface
5A, 5B linear portion
11 support film
12 intermediate resin layer
13 underlying layer
20 electrically conductive film
30 raised portion
100 display device
X intersecting part
C center of intersecting part

1. An electrically conductive film comprising:
a film-like base material; and
a resin layer and an electrically conductive part provided on one or both main surfaces of the base material; wherein
the resin layer has a pattern including a linear trench,
the electrically conductive part has a portion provided in the linear trench, and
the resin layer has raised portions formed along the trench on both sides of the linear trench, the raised portions raised in a thickness direction of the resin layer.

2. The electrically conductive film according to claim 1, wherein
a main surface of the resin layer positioned on a side opposite to the base material includes a parallel surface parallel to the main surface of the base material, and
a height of the raised portions with respect to the parallel surface is greater than or equal to 0.17 μm.

3. The electrically conductive film according to claim 1, wherein
a height of the electrically conductive part from the base material is smaller than a height of the raised portions from the base material.

4. The electrically conductive film according to claim 1, wherein
the pattern includes a plurality of the linear trenches intersecting each other.

5. The electrically conductive film according to claim 4, wherein
the pattern is a mesh-like pattern.

6. The electrically conductive film according to claim 4, wherein
a height of the raised portion from the base material in the vicinity of an intersecting part where the two linear trenches intersect is larger than a height of the raised portion from the base material at a position away from the intersecting part.

7. A display device comprising the electrically conductive film according to claim 1.

8. A method for manufacturing an electrically conductive film comprising:
pushing a mold having a linear protrusion into a resin layer provided on one or both main surface sides of a film-like base material, and then pulling out the mold from the resin layer to form a pattern including a linear trench in the resin layer; and
forming an electrically conductive part including a portion provided in the linear trench; wherein
the mold is pushed into the resin layer such that the resin layer forms raised portions raised in a thickness direction of the resin layer along the trench on both sides of the linear trench.

9. The method according to claim 8, wherein
a main surface positioned on a side opposite to the base material of the resin layer having the pattern includes a parallel surface parallel to the main surface of the base material, and
a height of the raised portions with respect to the parallel surface is greater than or equal to 0.17 μm.

10. The method according to claim 8, wherein
a height of the electrically conductive part from the base material is less than a height of the raised portion from the base material.

11. The method according to claim 8, wherein
the pattern includes a plurality of the linear trenches intersecting each other.

12. The method according to claim 11, wherein
the pattern is a mesh-like pattern.

13. The method according to claim 11, wherein
a height of the raised portions from the base material in the vicinity of an intersecting part where the two linear trenches intersect is larger than a height of the raised portions from the base material at a position away from the intersecting part.

14. The method according to claim 8, wherein
the resin layer before the mold is pushed in comprises a photocurable resin composition, and
the resin layer is cured by irradiating the resin layer with ultraviolet rays in a state where the mold is pushed into the resin layer.

15. The method according to claim 8, wherein
the electrically conductive part is formed by a plating method.

16. An electrically conductive film manufactured by the method according to claim 1.
